(19) United States
(12) Patent Application Publication
(10) Pub. No.: US 2022/0308466 A1
(43) Pub. Date: Sep. 29, 2022

(54) DEVICE FOR CLEANING A SURFACE IN THE INTERIOR OF AN OPTICAL SYSTEM

(71) Applicant: CARL ZEISS SMT GMBH, Oberkochen (DE)

(72) Inventors: Jovana-Maria DIESCH, Neu-Ulm (DE); Benjamin Sigel, Aalen (DE); Thomas Petasch, Aalen (DE)

(21) Appl. No.: 17/691,667

(22) Filed: Mar. 10, 2022

Related U.S. Application Data
(63) Continuation of application No. PCT/EP2020/075182, filed on Sep. 9, 2020.

(30) Foreign Application Priority Data
Sep. 12, 2019 (DE) 10 2019 213 914.0

(51) Int. Cl. G03F 7/20

(52) U.S. Cl. CPC G03F 7/70925

(57) ABSTRACT

The present disclosure relates to a device for cleaning a surface in the interior of an optical system. The device includes a rod-shaped element. The rod-shaped element includes an imager configured to image contaminates on the surface, and a cleaner configured to remove contaminates from the surface. The device also includes a distance sensor that is configured to measure the distance between the surface and the end of the rod-shaped element. The device also includes a connection element configured to be secured at an opening of the optical system, and the connection element includes a guide element configured to guide the rod-shaped element.

### CROSS-REFERENCE TO RELATED APPLICATION

This is a Continuation of International Application PCT/EP2020/075182, which has an international filing date of Sep. 9, 2020, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2019 213 914.0 filed on Sep. 12, 2019.

### FIELD OF THE INVENTION

The invention relates to a device for cleaning a surface in the interior of an optical system, in particular of a lithography system, to a use of the device for cleaning a surface in the interior of an optical system, and to a method for cleaning a surface in the interior of an optical system.

### BACKGROUND

Lithography is used for production of semiconductor components, such as integrated circuits and LCDs. The lithography process is conducted in what is called a projection exposure apparatus, which comprises an illumination system and a projection lens. The image of a mask (reticle) illuminated by the illumination system is projected by the projection lens onto a substrate (e.g. a silicon wafer) coated with a light-sensitive layer (photoresist) and disposed in the image plane of the projection lens, in order to transfer the mask structure to the light-sensitive coating of the substrate.

For the purposes of this application, a lithography system is understood as meaning an optical system that can be used in the field of lithography. Besides the projection exposure apparatus described above, which includes the optical subsystems of the illumination system and the projection lens mentioned above and which serves for producing semiconductor components, the optical system can also be an inspection system for inspecting a mask (also called a reticle hereinafter) used in a lithography system, or for inspecting a semiconductor substrate (also called a wafer hereinafter) to be structured, or a metrology system used for measuring a lithography system or parts thereof, for example for measuring a projection lens.

At the present time, light or radiation in the deep ultraviolet (DUV: deep ultraviolet, VUV: very deep ultraviolet) or in the far, extreme ultraviolet spectral range (EUV: extreme ultraviolet) is used, particularly, in lithography systems. Customary light wavelengths for DUV or VUV systems are currently between 248 nm and 193 nm. In order to achieve even higher lithographic resolutions, radiation ranging to soft X-ray radiation (EUV: extreme ultraviolet) or quasi hard X-ray radiation (XEUV: X-Ray EUV) having a wavelength of a few nanometres is used. In corresponding projection exposure apparatuses, this makes it possible to image extremely small structures onto wafers with a very high resolution.

In lithography systems designed for the EUV range, owing to the lack of availability of suitable light-transmissive refractive materials, mirrors are used as optical components for the imaging process.

In such systems, contaminates, for example resulting from particles, can lead to losses in performance, considerable damage or even to the complete failure of the entire apparatus. Therefore, diverse, and in some instances very laborious, methods for cleaning the individual components and/or for avoiding contaminates, in particular particle contaminates, are used in the production process.

It is nevertheless inevitable that contaminates, e.g., particle contaminates, may be present at the end of the production process after all the individual components or the modules composed of individual components have been assembled to form the overall system. Accordingly, it may be necessary to carry out cleaning of a surface in the interior of the optical system. Contamination of surfaces in the interior of the optical system can occur during operation of the lithography systems as well.

The surfaces situated in the interior of the optical system are generally difficult to access in the overall system. Access is afforded, for example, by openings in the optical system for the radiation to enter or exit or, in the case of optical systems constructed from exchangeable individual modules, by the openings produced after a module has been demounted. Moreover, primarily if the surface is an optical surface, such as the surface of a lens element or of a mirror, particular caution must be exercised because the surfaces can easily be damaged by being touched. Therefore, even for experts, cleaning that is usually carried out manually presents a great challenge and a great risk of damage and failure.

### SUMMARY

It is therefore an object of the techniques disclosed herein to provide a device for cleaning a surface in the interior of an optical system, a use of such a device for cleaning a surface in the interior of an optical system, and a method for cleaning a surface in the interior of an optical system. The techniques may enable as effective, rapid and reliable cleaning as possible with the least possible risk of damage and failure.

The objects of the disclosed techniques may be achieved by a device for cleaning a surface in the interior of an optical system, in particular of an EUV lithography system, comprising:

a rod-shaped element, wherein the rod-shaped element comprises:
a visualization unit (also referred to herein as an “imager”) configured to visualize or image contaminates on the surface, and
a cleaning unit (also referred to herein as a “cleaner”) configured to remove contaminates from the surface,
   a distance sensor, wherein the distance sensor is configured in such a way as to measure the distance between the surface and the end of the rod-shaped element, and
   a connection element configured in such a way that it can be secured at an opening of the optical system, and wherein the connection element comprises a guide element, with the aid of which the rod-shaped element can be guided.

The regions of the contaminated surface which are situated in the interior of the optical system can be reached by the rod-shaped element when the rod-shaped element is inserted into the optical system. The initial insertion may be a manual insertion through an opening in the optical system.

In order to clean the surface of contaminates, in particular particles, fibres or fluff, the contaminates may have to be visualized on a predefined surface section by a visualization unit and then be removed from the surface with the aid of the cleaning unit. In this case, the visualization unit initially serves for finding and for visualizing the contaminates. The contaminates found can then be assessed and, if necessary, removed from the surface by the cleaning unit. After cleaning by the cleaning unit, the visualization unit can also be used to verify the cleaning result.

In order to minimize the risk of damage and failure, as well as for effective cleaning of the surfaces, it may be beneficial for a distance sensor to be integrated into the device. The distance sensor may measure the distance between the surface and the end of the rod-shaped element. On the one hand, the surface must not be touched, in order to avoid damage to the surface or positional displacements. On the other hand, for effective cleaning, the distance between the surface and the end of the rod-shaped element must be less than a maximum distance so that the cleaning unit functions optimally. Preferably, care must be taken here to ensure that the distance sensor functions in all spatial directions, and not just in a direction parallel to the rod-shaped element. For this purpose, it may be beneficial to integrate the distance sensor into the device for cleaning such that shading by the other elements, in particular by the cleaning unit and the visualization unit, does not occur.

The interplay of the connection element, which is adapted to the outer geometry of the optical system and can be secured there, and the guide element facilitates the usually manual insertion of the rod-shaped element. In this case, with guidance of the rod-shaped element, a controlled movement of the rod-shaped element from the opening of the optical system toward the surface to be cleaned (translation) and also a rotary movement about the pivot of the guide element, i.e., a rotation about the pivot, are made possible. Thus the entire surface in the interior can ideally be reached.

In one example embodiment, the guide element can comprise a ball-and-socket joint, which allows a rotary movement about the pivot in addition to translation into the interior of the system. The rod-shaped element is mounted rotatably about the pivot of the ball-and-socket joint and, given sufficient structural space, can be displaced arbitrarily at both solid angles.

In another example embodiment, the guide element further comprises a securing unit for securing the rod-shaped element. If the end of the rod-shaped element is situated, for example, at a location of the surface at which a contaminate was visualized by the visualization unit and if there is a suitable distance with respect to the surface, the rod-shaped element can be secured and then the cleaning can be carried out without the risk of failure. Preferably, for this purpose, the rod-shaped element can be clamped with the aid of a screw, for example. The generation of further particles should be avoided or minimized in this case. As an alternative to screwing, clamping by an eccentric would also be conceivable. Moreover, it is possible, conversely, to clamp the rod-shaped element in the non-actuated state and to make it movable by the introduction of force and the associated release of the clamping.

In one preferred embodiment, the rod-shaped element also comprises a kinematic system for angled bending, whereby optical units that are not accessible rectilinearly can be made reachable. Said kinematic system can be simple joints that can be actuated in their degree of freedom.

If the connection element furthermore comprises a displacement unit for fine positioning, the position of the rod-shaped element relative to the surface to be cleaned can be further controlled and optimized by actuation of the displacement unit. It is then possible, for example, after manual coarse positioning, to fix the rod-shaped element. Subsequently, with the aid of the displacement unit, it is possible to move to the optimum position with regard to the exact location of the contaminate and the optimum distance with respect to the surface with the aid of the visualization unit and the distance sensor. As a result, it is possible to carry out effective cleaning with a low risk of failure.

In yet another example embodiment, the displacement unit for fine positioning is operated by way of a (manual) crank or a controllable actuator. Diverse actuators that can be used to implement a translational movement are conceivable for this. For example, the actuators may operate according to the piezo-crawler principle, or the actuators may be hydraulically or pneumatically/hydraulically/electrically operated linear drives.

In still another example embodiment, the visualization unit and the cleaning unit are arranged in direct proximity to one another in order to enable as compact a design as possible. This not only facilitates the insertion and positioning in the interior of the optical system, but has the effect that if a contaminate, in particular a particle, fluff or a fibre, was able to be visualized with the aid of the visualization unit, said contaminate can be removed directly with the aid of the cleaning unit arranged in direct proximity, without once again displacing the device for cleaning. If the distance between the visualization unit and the cleaning unit is too large, either the cleaning performance of the cleaning unit is impaired or the cleaning unit has to be displaced once again before cleaning, which entails the risk that the contaminate cannot be removed optimally because it has not been found optimally.

Furthermore, in one example embodiment, the rod-shaped element can be enclosed by a tube and the distance sensor can be integrated into the tube in order to enable an even more compact design. In the case of the location of the distance sensor, care should be taken to ensure that the latter functions in all spatial directions, and not just in a direction parallel to the rod-shaped element. In particular, shading into a spatial region by the other elements must be excluded.

In one preferred embodiment, the rod-shaped element further comprises an anti-collision protection element (also referred to herein as a “collision avoidance element”) fitted at the end of the rod-shaped element. Said anti-collision protection element can be, in particular, plastic lamellae, PMC tape or Kalrez material. If a surface, specifically an optical surface, were indeed touched, it would be better protected by the anti-collision protection element and the risk of damage or failure would thus additionally be minimized.

In one preferred embodiment, the visualization unit is an endoscope (i.e., a video endoscope), a boroscope, a camera, or a detector. All of these types of visualization units are suitable for visualizing contaminates on the surface and for transmitting the signal towards the outside to an image generator, such as a screen, for example.

In another example embodiment, the device for cleaning can further comprise an illumination unit designed in such a way that it illuminates the surface section visualized by the visualization unit. This can involve for example a ring electrode or an LED ring, wherein the LED ring is switchable as far as possible sequentially. An improved illumination of the contaminates to be visualized by grazing light can thus be achieved. Since the surface to be cleaned is a surface in the interior of the optical system, the lighting conditions are not ideal and can be improved by such an illumination unit, whereby the cleaning result can be improved.

In this case, the illumination unit can also be integrated directly in the visualization unit.

According to other example embodiments, an illumination with different spectra can be effected in this case. In this regard, it is possible to use an illumination with UV light, for example, in which organic contamination can be particularly lit up and identified more easily.

Likewise, an indirect illumination can also lead to a good visualization of the contamination.

In one example embodiment, the visualization can be effected by a scattered light method. For this purpose, the light, for example laser light, generated by the illumination unit is shone onto the predefined surface section and the scattered light generated is detected, for example by a suitably positioned camera or a detector. As a result of the detection of the scattered light, the resolution can be improved and for example smaller particles can thus be visualized.

In one example embodiment, the device for cleaning can further comprise a shield, which is fitted to the rod-shaped element in such a way that it can be folded out after insertion into the optical system and is configured such that it blocks extraneous light, in particular back-reflections from other surfaces, in the folded-out state. Blocking the extraneous light has the effect that only light and thus information passes from the surface section to be visualized into the visualization unit and disturbing superimpositions can be blocked and the visualization and subsequently the cleaning can thus be improved.

In another example embodiment, the cleaning unit comprises a suction extractor and/or another device for detaching the contaminates from the surface. In this case, the suction extractor is able to extract the contaminates, particularly if they are particles, fluff or fibres, by suction from the surface. The another device for detaching the contaminates can be, for example, a compressed air probe or a CO₂ jet unit, which can detach contaminates from the surface with the aid of CO₂-pellets or CO₂ snow.

Depending on the location or type of the surface in the optical system, it may be sufficient only to detach the contaminate from the surface. With the combination of a suction extractor and a detaching device, however, the contaminates can firstly be detached and then be extracted by suction and thus be completely removed from the optical system.

Furthermore, the cleaning unit can also be a surface measuring probe. The latter can detach contaminates using compressed air and then extract them by suction. The extracted gas is subsequently fed to an analysis unit, for example an RGA (residual gas analysis) unit. The exact constitution of the contaminate can thus be examined.

In a further example embodiment, the device for cleaning further comprises a sampling element, such as a Kalrez material, a PMC tape or a clean tip, fitted at the end of the rod-shaped element. The contaminates would thus be able to be removed from the optical system and then be able to be viewed and analysed using, for example, a scanning electron microscope (SEM) or another sample analysis device. Knowledge of the material, under certain circumstances, allows the cause of the contamination to be deduced and then remedied.

In one specific example embodiment, the distance sensor is a capacitive or ultrasonic sensor.

In one example embodiment, the distance sensor outputs acoustic or optical signals, wherein the signals are such that conclusions about the distance between the surface and the end of the rod-shaped element can be drawn therefrom. This can involve an acoustic signal that varies for example the pitch or the frequency of the signal as the surface is approached more closely, in order to warn the user. It is likewise conceivable for an optical signal to be output instead of or in support of said acoustic signal.

Furthermore, the device for cleaning can comprise a control unit. With accurate knowledge of the geometry and location of the surface, it is possible to move precisely to the surface in the interior of the optical system with the aid of the control unit and the displacement unit. Automated cleaning of the surface is thus made possible.

In this case, the signal of the distance sensor can also be used as an input for the control unit. In this regard, the device for cleaning can also move to the surface in an automated manner with the aid of the displacement unit controlled by the control signal, and efficient and low-risk cleaning can thus be made possible.

Furthermore, the techniques of this disclosure relate to the use of the device according to any of the preceding embodiments for cleaning a surface in the interior of an optical system, in particular of an EUV lithography system.

Furthermore, the techniques relate to a method for cleaning a surface in the interior of an optical system, comprising the steps of:
securing a connection element at an opening of the optical system, wherein the connection element is adapted to the outer geometry of the optical system and wherein the connection element comprises a guide element,
inserting a rod-shaped element, which comprises a visualization unit, a cleaning unit and a distance sensor, through the guide into the interior of the optical system,
using the visualization unit for visualizing the contaminate,
moving the rod-shaped element to a suitable distance from the surface on the basis of the distance signal, and
subsequent cleaning with the aid of the cleaning unit.

Further advantageous configurations and aspects of the techniques of this disclosure are the subject matter of the exemplary embodiments of the invention described below. In the text that follows, the techniques of this disclosure are explained in more detail on the basis of example embodiments and with reference to the accompanying figures.

### BRIEF DESCRIPTION OF THE DRAWINGS

In the figures:

FIG. 1 shows a basic schematic diagram concerning the construction of a DUV lithography apparatus

FIG. 2 shows a basic schematic diagram concerning the construction of an EUV lithography apparatus

FIG. 3 shows a schematic illustration of a device for cleaning in accordance with a first embodiment of the invention, said device being attached to a lithography system

FIG. 4 shows a schematic illustration of a device for cleaning in accordance with a second embodiment of the invention, said device being attached to a lithography system

### DETAILED DESCRIPTION

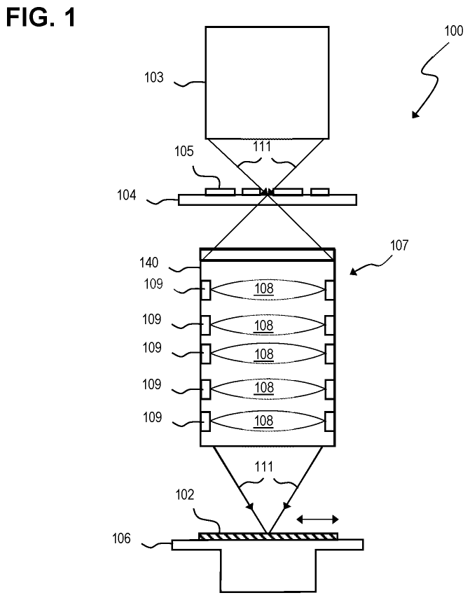

FIG. 1 illustrates an exemplary DUV projection exposure apparatus 100. The projection exposure apparatus 100 comprises an illumination system 103, a device known as a reticle stage 104 for receiving and exactly positioning a reticle 105, by which the later structures on a wafer 102 are determined, a wafer holder 106 for holding, moving and exactly positioning the wafer 102 and an imaging facility, specifically a projection lens 107, with multiple optical elements 108, which are held by way of mounts 109 in a lens housing 140 of the projection lens 107.

The optical elements 108 may be designed as individual refractive, diffractive and/or reflective optical elements 108, such as, for example, lens elements, mirrors, prisms, terminating plates and the like.

The basic functional principle of the projection exposure apparatus 100 is to image the structures of the reticle 105 onto the wafer 102.

The illumination system 103 provides a projection beam 111 in the form of electromagnetic radiation, which is required for the imaging of the reticle 105 onto the wafer 102. A laser source, a plasma source or the like may be used as the source of this radiation. The radiation is shaped in the illumination system 103 by optical elements such that the projection beam 111 has the desired properties with regard to diameter, polarisation, shape of the wavefront and the like when it is incident on the reticle 105.

An image of the reticle 105 is generated by the projection beam 111 and transferred from the projection lens 107 onto the wafer 102 in an appropriately reduced form. In this case, the reticle 105 and the wafer 102 may be moved synchronously, so that regions of the reticle 105 are imaged onto corresponding regions of the wafer 102 virtually continuously during a so-called scanning operation.

For the entrance and exit of the radiation and also at the transition between the individual subsystems, for example from the illumination system 103 into the projection optical unit 107, openings (not shown in the figure) can be present. Said openings can be used as access to the surfaces in the interior of the optical system. In addition, the optical system can be constructed from individual submodules, which can be demounted individually from the optical system for better maintenance. Consequently, further openings (not shown in the figure) arise in the event of maintenance and can be used as access to the surfaces.

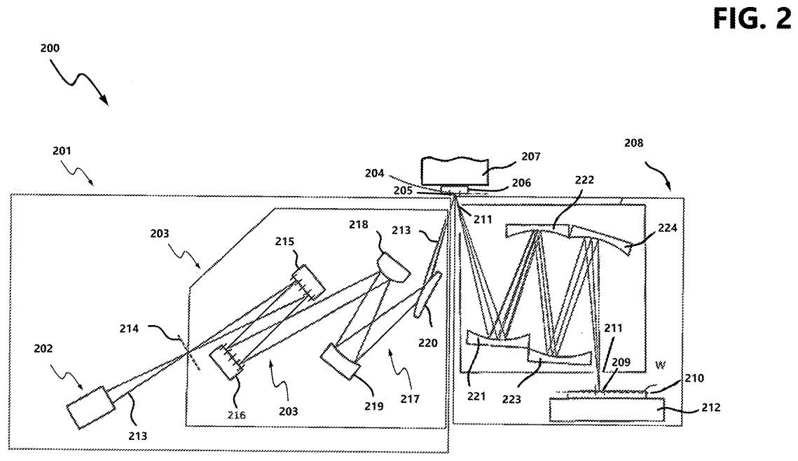

FIG. 2 shows an example of the basic construction of an EUV lithography system 200 to which the techniques of the present disclosure may be applied. An illumination system 201 of the lithography system 200 comprises, besides a radiation source 202, an optical unit 203 for the illumination of an object field 204 in an object plane 205. A reticle 206 arranged in the object field 204 is illuminated, said reticle being held by a reticle holder 207, illustrated schematically. The radiation source 202 can emit EUV radiation 213, in particular in the range of between 5 nanometres and 30 nanometres. Optical elements 215 to 220, which may be configured with different optical properties, may be mechanically adjusted to control the radiation path of the EUV radiation 213. In the case of the EUV projection exposure apparatus 200 illustrated in FIG. 2, the optical elements are configured as adjustable mirrors in suitable embodiments, which are mentioned merely by way of example below.

The EUV radiation 213 generated by the radiation source 202 is aligned by a collector integrated in the radiation source 202 in such a way that the EUV radiation 213 passes through an intermediate focus in the region of an intermediate focal plane 214 before the EUV radiation 213 impinges on a field facet mirror 215. Downstream of the field facet mirror 215, the EUV radiation 213 is reflected by a pupil facet mirror 216. With the aid of the pupil facet mirror 216 and an optical assembly 217 having mirrors 218, 219, 220, field facets of the field facet mirror 215 are imaged into the object field 204.

The projection optical unit 208 images the object field 204 into an image field 209 in an image plane 210. A structure on the reticle 206 is imaged on a light-sensitive layer of a wafer W arranged in the region of the image field 209 in the image plane 210, said wafer being held by a wafer holder 212 that is likewise illustrated schematically. By way of example, the optical elements 221 to 224 are used for this purpose.

For the entrance and exit of the radiation and also at the transition between the individual subsystems, for example from the illumination system 201 into the projection lens 208, openings 211 may be included in EUV lithography system 200. Said openings can be used as access to the surfaces in the interior. In addition, the optical system can be constructed from individual submodules, which can be demounted individually from the optical system for better maintenance. Consequently, further openings (not shown in the figure) arise in the event of maintenance and can be used as access to the surfaces.

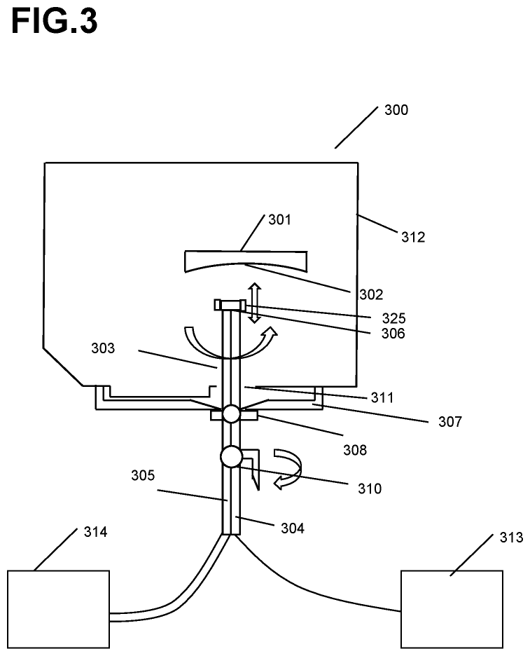

FIG. 3 shows a schematic illustration of a device for cleaning in accordance with a first embodiment of the techniques of this disclosure, said device being attached to a lithography system. In this case, for the sake of clarity, the optical system 300 is shown only by a housing 312 having an opening 311 and an optical element 301 having a surface 302 to be cleaned, said optical element 301 being situated in the interior. Here in the case of a lithography system, the surface of the optical elements is usually equipped either with a highly reflective layer system in the case of mirrors, or with an antireflection layer system in the case of a refractive optical element, such as a lens element, for example. The layer systems usually consist of complex sequences of many individual layers of different materials. In the case of these layer systems, even small defects or contaminates thereon can have an adverse effect on the performance of the optical system. The surface 302 to be cleaned can also be a housing wall situated in the interior or an arbitrary surface of structural or mechanical components, for example. Even if these surfaces are typically not damaged as easily or the contamination thereof does not directly affect the performance of the optical system, particles, fluff or fibres, for example, must also be removed from therefrom, if only so that they do not spread from there to other surfaces, for example optical surfaces.

In this case, in the present exemplary embodiment, the device for cleaning a surface 302 in the interior of an optical system 300 comprises a rod-shaped element 303, in which the visualization unit 304 and the cleaning unit 305 are arranged in direct proximity to one another, in order to enable as compact a design as possible. For construction reasons, the rod-shaped element in the given exemplary embodiment can be enclosed by a tube, for example made of aluminium. The compact design facilitates the insertion and positioning in the interior of the optical system 300 and primarily has the effect that if a contaminate, in particular resulting from particles, fluff or fibres, was visualized with the aid of the visualization unit 304, said contaminate can subsequently be removed directly with the aid of the cleaning unit 305 arranged in direct proximity, without once again displacing the device for cleaning. If the distance between visualization unit 304 and cleaning unit 305 is too large, either the cleaning performance of the cleaning unit 305 is impaired or the cleaning unit 305 has to be displaced once again before cleaning, which entails the risk that the contaminate cannot be removed optimally because it has not been found optimally.

For this purpose, the visualization unit 304, for example an endoscope (i.e., a video endoscope), a boroscope, a camera, or a detector, is configured to visualize contaminates on the surface 302. The signal can be transmitted towards the outside to an image generator 313, such as a screen, for example. The contaminates on the surface 302 are not illustrated, for the sake of clarity. In this case, the visualization unit 304 serves firstly for finding and for visualizing the contaminates. The contaminates found can then be assessed and, if necessary, be removed from the surface 302 by the cleaning unit 305. Secondly, after the cleaning, the cleaning state can also be verified and documented.

The cleaning unit 305 configured to remove contaminates from the surface 302 can contain for example a suction extractor and/or a device for detaching the contaminates from the surface. In this case, the suction extractor is able to extract the contaminates, particularly if they are particles, fluff or fibres, by suction from the surface. The detaching device can be, for example, a compressed air probe or a CO₂ jet unit, which can detach contaminates from the surface with the aid of CO₂ pellets or CO₂ snow.

Depending on the location or type of the surface 302 in the optical system, it may be sufficient only to detach the contaminate from the surface 302. With the aid of a combination of a suction extractor and a detaching device, however, the contaminates can firstly be detached and then be extracted by suction and thus be completely removed from the optical system 300.

Furthermore, the cleaning unit 305 can also be a surface measuring probe. The latter can firstly detach contaminates with the aid of compressed air and then extract them by suction. The extracted gas is subsequently fed to an analysis unit 314, for example an RGA (Residual Gas Analysis) unit. The exact constitution of the contaminate can thus be examined. The residual gas analysis unit can be a mass spectrometer, for example.

In this case, the distance sensor 306 is integrated into the end of the rod-shaped element 303 such that it can measure the distance between the surface 302 and the end of the rod-shaped element 303. By way of example, the distance sensor is a capacitive or ultrasonic sensor.

Measuring the distance between the end of the rod-shaped element 303 and the surface 302 minimising the risk of damage and failure, as well as for effective cleaning of the surfaces. On the one hand, the surface 302 must not be touched, in order to avoid damage to the surface or positional displacements of the elements, specifically of the optical elements. On the other hand, for effective cleaning, the distance between the surface 302 and the end of the rod-shaped element 303 must be less than a maximum distance in order that the cleaning unit 305 functions optimally. Preferably, the cleaning unit 305 must be guided to the surface 302 to be cleaned to a distance of less than 10 mm. Care must be taken to ensure that the distance sensor 306 functions in all spatial directions, and not just in a direction parallel to the rod-shaped element 303. Accordingly, it is beneficial to integrate the distance sensor 306 into the device for cleaning such that shading by the other elements, in particular by the cleaning unit 305 and the visualization unit 304 does not occur.

For cleaning purposes, the connection element 307) is first secured at an opening 311 of the optical system 300. As already explained above, the openings of the optical system 300 can be an entrance or exit opening for the radiation. However, they can also be openings that arise in the event of maintenance, for example if a submodule is extracted from the optical system. The opening that arises in this case can likewise be used as access for the device for cleaning.

The connection element 307 can further comprise a guide element 308 via which the rod-shaped element 303 can be guided. First, the rod-shaped element 303 is inserted into the optical system 300 through the opening 311, usually manually, but with guidance from the guide element 308 included in the connection element 307. The guidance of the rod-shaped element by guide element 308 results in a controlled translational movement of the rod-shaped element from the opening of the optical system toward the surface 302 to be cleaned. Rotary movement of the rod-shaped element 303 about the pivot of the guide element 308 is also made possible. Thus the entire surface 302 in the interior can ideally be reached. In the present exemplary embodiment, the guide element 308 can comprise a ball-and-socket joint, which allows a rotary movement about a pivot in addition to translation into the interior of the system. The rod-shaped element 303 is mounted rotatably about the pivot of the ball-and-socket joint and, given sufficient structural space, can be displaced arbitrarily at both solid angles.

During the process, the distance sensor 306 can output acoustic or optical signals, wherein the signals are such that conclusions about the distance between the surface 302 and the end of the rod-shaped element 303 can be drawn therefrom. This can involve an acoustic signal that varies, for example, the pitch or the frequency of the signal as the surface 302 is approached more closely, in order to warn the user. It is likewise conceivable for an optical signal to be output instead of or in support of said acoustic signal.

Furthermore, the guide element 308 can comprise a securing unit for securing the rod-shaped element, said securing unit not being shown in FIG. 3. Thus, for example at a location of the surface at which a contaminate was visualized by the visualization unit 304 and given a predefined distance, which is measured by the distance sensor 306, the rod-shaped element 303 can be secured and then the cleaning can be carried out without the risk of failure. For this purpose, the rod-shaped element 303 can be clamped with the aid of a screw, for example. The generation of further particles should be avoided or minimized in this case. As an alternative to screwing, clamping by an eccentric would also be conceivable. Alternatively the converse principle that the rod-shaped element 303 is clamped in the non-actuated state and is made movable by the introduction of force and the associated release of the clamping. The rod-shaped element 303 can also include a kinematic system for angled bending, whereby optical units that are not accessible rectilinearly can be made reachable. Said kinematic system can be simple joints that can be actuated in their degree of freedom.

If the connection element 307 further comprises a displacement unit 310 for fine positioning, the position of the rod-shaped element 303 relative to the surface 302 to be cleaned can then be optimized further by actuation of the displacement unit 310. It is then possible, for example, after a manual coarse positioning, to first fix the rod-shaped element 303 and then, with the aid of the displacement unit 310, to head for the optimum position with regard to the exact location of the contaminate and the optimum distance with respect to the surface 302 with the aid of the visualization unit 304 and the distance sensor 306. In this case, the control can be implemented with, for example, the aid of a manual crank or alternatively by way of a controllable actuator. This possibility of fine positioning makes it possible to carry out effective cleaning with a low risk of failure. Diverse actuators that can be used to implement a translational movement are useable as a controllable actuator. Example actuators include actuators that operate according to the piezo-crawler principle as well as hydraulically or pneumatically/hydraulically/electrically operated linear drives.

Furthermore, the device for cleaning can comprise an anti-collision protection element 325 which is fitted at the end of the rod-shaped element. Said protection element can be, in particular, plastic lamellae, PMC tape or Kalrez material. If a surface 302, specifically an optical surface, were indeed touched, it would be better protected by the anti-collision protection element 325 and the risk of damage or failure would thus additionally be minimized.

Furthermore, the device for cleaning can comprise a control unit, not shown in FIG. 3. With accurate knowledge of the geometry and location of the surface 302, it is possible to move the device for cleaning unit 305 to the surface 302 in the interior of the optical system 300 in an automated manner with the aid of the control unit and the displacement unit 310, as a result of which automated cleaning of the surface 302 is made possible.

By way of example, it is conceivable for the entire surface 302 to have been recorded beforehand with the aid of a suitable recording device, for example a camera. This may have been effected by a single recording or, in the case of larger surfaces, by a sequence of recordings that are correspondingly strung together and suitably combined. The surface cartography available as a result can yield the position of the contaminates on the surface given a suitable recording. The data can then be used to move to, and clean, the contaminated locations on the surface 302 in a targeted manner rapidly and effectively with the aid of the control unit.

In this case, the signal of the distance sensor 306 can also be used as an input for the control unit. In this regard, the cleaning unit 305 can also move to the surface 302 in an automated manner with the aid of the displacement unit 310 controlled by the control signal, and efficient and low-risk cleaning can thus be made possible.

Generally, care must be taken to ensure that all materials used in the device for cleaning are permitted to be employed for use in a cleanroom for lithography. This means that the materials used must exhibit little outgassing and few particles and are not permitted to leave any HIO critical materials or any imprints on the surface.

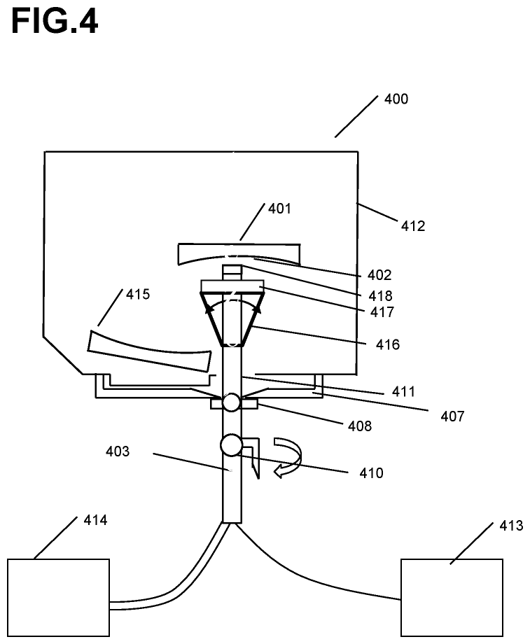

FIG. 4 shows a schematic illustration of a device for cleaning in accordance with a second embodiment of the techniques of the present disclosure, said device being attached to a lithography system. In this case, for the sake of clarity, the optical system 400 is shown only by a housing 412 having an opening 411 and two optical elements 401 and 415 situated in the interior. The surface 402 to be cleaned is the surface of the optical element 401.

In this case, the exemplary embodiment shown in FIG. 4 comprises a rod-shaped element 403 already explained in FIG. 3, which comprises the components of a distance sensor, a visualization unit and a cleaning unit, these components not being shown in FIG. 4, and a connection element 407, the associated guide element 408. Furthermore, the embodiment can comprise a securing unit (not shown) with an optional displacement unit 410 for fine positioning and/or an anti-collision protection element and/or a control unit. These components have been described in detail on the basis of the exemplary embodiment in FIG. 3.

Furthermore, the device of the exemplary embodiment shown in FIG. 4 comprises an illumination unit 417 designed in such a way that it illuminates the surface section visualized by the visualization unit. This can involve for example a ring electrode or an LED ring, wherein the LEDs of the LED ring may be sequentially illuminated. An improved illumination of the contaminates to be visualized by grazing light can thus be achieved. Since the surface 402 to be cleaned is a surface in the interior of the optical system 400, the lighting conditions are not ideal and can be improved by such an illumination unit 417, whereby the cleaning result can be improved.

By way of example, an illumination with different spectra can be effected in this case. In this regard, it is possible to use an illumination with UV light, for example, in which organic contamination can be particularly lit up and identified more easily.

Likewise, an indirect illumination can also lead to a good visualization of the contamination.

In addition, the device for cleaning in FIG. 4 comprises a shield 416, which is fitted to the rod-shaped element 403 in such a way that it can be folded out after insertion into the optical system 400 and is configured such that it blocks extraneous light, in particular back-reflections from other surfaces, such as the surface of the optical element 415, for example, in the folded-out state. Blocking the extraneous light has the effect that only light and thus information passes from the surface section to be visualized into the visualization unit 404 and disturbing superimpositions can be blocked and the visualization and subsequently the cleaning can thus be improved.

The illumination unit is integrated into the shield 416 in the present exemplary embodiment. However, it can also be fitted at the end of the rod-shaped element 403 or directly in the visualization unit 404.

Furthermore, the device for cleaning in the embodiment present in FIG. 4 comprises a sampling element 418, in particular a Kalrez material, a PMC tape or a clean tip, said sampling element being fitted at the end of the rod-shaped element 403. By approaching and touching the surface 402 to be cleaned, the contaminates can be at least partly removed from the optical system and then be viewed and analysed using suitable devices 414, such as a light microscope, a scanning electron microscope (SEM) or other devices configured for sample analysis. Knowledge of the material, under certain circumstances, allows the cause of the contamination to be deduced and then remedied.

The embodiment described in FIG. 4 comprises both an illumination unit 417, a shield 416 and a sampling element 418. Further advantageous embodiments can also comprise only one of the three components mentioned or combinations of in each case two of the components.

The embodiments described with reference to FIGS. 3 and 4 and their modifications can all be used for cleaning a surface 302, 402 in the interior of an optical system 300, 400, respectively.

Furthermore, the invention relates to a method for cleaning a surface 302, 402 in the interior of an optical system 300, 400, respectively, comprising the steps of
securing a connection element at an opening of the optical system, wherein the connection element is adapted to the outer geometry of the optical system and wherein the connection element comprises a guide element,
inserting a rod-shaped element , which comprises a visualization unit , a cleaning unit and a distance sensor, through the guide element into the interior of the optical system,
using the visualization unit for visualizing the contaminate,
moving the rod-shaped element to a suitable distance from the surface on the basis of the distance signal of the distance sensor, and
subsequent cleaning with the aid of the cleaning unit.

What is claimed is:

1. An apparatus for cleaning a surface in an interior of an optical system comprising:
a rod-shaped element, wherein the rod-shaped element comprises:
an imager configured to image contaminates on the surface, and
a cleaner configured to remove contaminates from the surface;
a distance sensor configured to measure a distance between the surface and an end of the rod-shaped element; and
a connection element configured to be secured at an opening of the optical system and comprising a guide element configured to guide the rod-shaped element.

2. The apparatus of claim 1, wherein the guide element comprises a ball-and-socket joint.

3. The apparatus of claim 1, wherein the guide element comprises a securing unit configured to secure the rod-shaped element.

4. The apparatus of claim 3, wherein the guide element comprises a displacement unit configured to finely position the rod-shaped element.

5. The apparatus of claim 4, wherein the displacement unit is operated by a manual crank or an actuator.

6. The apparatus of claim 1, wherein the imager and the cleaner are arranged in direct proximity to one another.

7. The apparatus of claim 1, wherein the rod-shaped element is enclosed by a tube, and wherein the distance sensor is integrated into the tube.

8. The apparatus of claim 1, wherein the rod-shaped element comprises a collision avoidance element fitted at the end of the rod-shaped element.

9. The apparatus of claim 1, wherein the imager comprises an endoscope, a boroscope, a camera, or a detector.

10. The apparatus of claim 1, further comprising an illumination unit configured to illuminate at least a section of the surface imaged by the imager.

11. The apparatus of claim 1, further comprising a shield fitted to the rod-shaped element such that the shield folds out after insertion into the optical system and blocks light from other surfaces of the optical system when folded-out after insertion into the optical system.

12. The apparatus of claim 1, wherein the cleaner comprises at least one of a suction extractor or a detaching device configured to detach the contaminates from the surface.

13. The apparatus of claim 1, wherein the cleaner comprises a surface measuring probe.

14. The apparatus of claim 1, further comprising a sampling element fitted at the end of the rod-shaped element, wherein the sampling element comprises a Kalrez material, a PMC tape or a clean tip.

15. The apparatus of claim 1, wherein the distance sensor comprises a capacitive or ultrasonic sensor.

16. The apparatus of claim 1, wherein the distance sensor outputs acoustic or optical signals indicative of a distance between the surface and the end of the rod-shaped element.

17. The apparatus of claim 1, wherein the guide element is configured to guide the rod-shaped element into the interior.

18. An optical system comprising an Extreme Ultraviolet (EUV) lithography system and an apparatus according to claim 1.

19. A method for cleaning a surface in an interior of an optical system comprising:
securing a connection element at an opening of the optical system, wherein the connection element is adapted to an outer geometry of the optical system and wherein the connection element comprises a guide element;
inserting, through the guide element into the interior of the optical system, a rod-shaped element comprising an imager, a cleaner and a distance sensor;
imaging a contaminate using the imager;
moving the rod-shaped element to a given distance from the surface based on a distance signal of the distance sensor; and
cleaning the contaminate using the cleaner.
